(19) United States
(12) Patent Application Publication
(10) Pub. No.: US 2025/0169056 A1
(43) Pub. Date: May 22, 2025

(54) SEMICONDUCTOR MEMORY DEVICE HAVING HYBRID CAPACITOR

(71) Applicant: Sahmyook University Industry-Academic Cooperation Foundation, Seoul (KR)

(72) Inventors: Dong Jun SEONG, Seongnam-si (KR); Min Kyu YANG, Namyangju-si (KR); Hyun Kyu SEO, Namyangju-si (KR); Se Yeon JEONG, Incheon (KR); Su Yeon LEE, Seoul (KR); Jun Hyuk LEE, Seoul (KR); Hyo Jong An, Seoul (KR); Tae Heon KIM, Yongin-si (KR); Sang Kyum KIM, Gwangmyeong-si (KR)

(73) Assignee: Sahmyook University Industry-Academic Cooperation Foundation, Seoul (KR)

(21) Appl. No.: 18/539,262

(22) Filed: Dec. 14, 2023

(30) Foreign Application Priority Data
Nov. 20, 2023 (KR) 10-2023-0160539

(51) Int. Cl. H10B 12/00; H01G 11/04

(52) U.S. Cl. CPC H10B 12/315; H01G 11/04; H10B 12/482

(57) ABSTRACT

A semiconductor memory device having a hybrid capacitor includes a cell transistor including a gate structure provided on a substrate, and a first impurity region and a second impurity region disposed on the substrate at both sides of the gate structure, a bit line structure electrically connected to the first impurity region, and a hybrid capacitor including a control element electrically connected to the second impurity region and configured to control the flow of current by changing a resistance thereof according to a magnitude of an applied voltage, and a cell capacitor connected in series to the control element and functioning as a storage node configured to store charges, wherein the control element includes a first electrode, a switching material layer, and a second electrode, and the cell capacitor includes the second electrode, a capacitor dielectric layer, and a third electrode.

### CROSS-REFERENCE TO RELATED APPLICATION

This application claims priority to and the benefit of Korean Patent Application No. 10-2023-0160539, filed on Nov. 20, 2023, the disclosure of which is incorporated herein by reference in its entirety.

### BACKGROUND

### 1. Field of the Invention

The present invention relates to a semiconductor memory device having a hybrid capacitor, and more particularly, to a semiconductor memory device having a hybrid capacitor in which a control element that controls the flow of current to reduce leakage current and a cell capacitor that functions as a storage node are connected in series.

### 2. Discussion of Related Art

Due to characteristics such as miniaturization, multi-functionality, and/or low manufacturing costs, semiconductor devices are in the spotlight as an important factor in the electronics industry. Semiconductor devices may be classified into semiconductor memory devices that store logic data, semiconductor logic devices that compute and process the logic data, and hybrid semiconductor devices that include memory elements and logic elements.

In recent years, the amount of data processed by semiconductor memory devices and the speed at which the data is processed have increased, and thus, semiconductor memory devices are increasing in capacity and becoming more highly integrated. However, as semiconductor memory devices, e.g., dynamic random-access memory (DRAM) devices, become more highly integrated, there is an increase in leakage current. The increase in leakage current may degrade the reliability of DRAM devices, such as their refresh characteristics and retention characteristics.

For example, an increase in refresh time and a decrease in retention time may increase the power consumption of a DRAM device. In addition, a large area of an error correction code (ECC) circuit for refresh control inhibits an increase in integration density of the DRAM device.

Accordingly, it is necessary to develop a semiconductor memory device capable of reducing leakage current in a circuit without affecting the implementation of a high-capacity and highly integrated DRAM device.

The background technique of the present invention is disclosed in Korean Patent Application Publication No. 10-2023-0006206.

### SUMMARY OF THE INVENTION

The present invention is directed to providing a semiconductor memory device having a hybrid capacitor, capable of reducing leakage current in a circuit without affecting the implementation of a high-capacity and highly integrated dynamic random-access memory (DRAM) device.

Objectives to be achieved by the embodiments of the present invention are not limited to the above-described objective, and other objectives, which are not described above, may be clearly understood by those skilled in the art through the following specification.

According to an aspect of the present invention, there is provided a semiconductor memory device including a hybrid capacitor, the semiconductor memory device including a cell transistor including a gate structure provided on a substrate, and a first impurity region and a second impurity region disposed on the substrate at both sides of the gate structure, a bit line structure electrically connected to the first impurity region, and a hybrid capacitor including a control element electrically connected to the second impurity region and configured to control the flow of current by changing a resistance thereof according to the magnitude of an applied voltage, and a cell capacitor connected in series to the control element and functioning as a storage node configured to store charges, wherein the control element includes a first electrode, a switching material layer disposed on the first electrode and including a chalcogen compound containing a chalcogen element, and a second electrode provided on the switching material layer, and the cell capacitor includes the second electrode, a capacitor dielectric layer provided on the second electrode and including a high-k dielectric material having a dielectric constant higher than that of silicon oxide, and a third electrode provided on the capacitor dielectric layer.

According to one embodiment, the switching material layer may include a chalcogen compound obtained by combining at least one of Te and Se, which are chalcogen elements, and at least one selected from Ge, Sb, Bi, Al, Zn, B, Pb, Sn, Ag, As, S, Si, In, Ti, Ga, P, O, and C.

According to one embodiment, the switching material layer may include A₁₋ₓTeₓ (where A includes C, B, Al, Zn, or Si, and 0.5≤x<1), Ge_{1-y}Se_{y} (where 0.5≤y<1), or GeₐSe_{b}Sb_{1-a-b} (where 0<a<0.5, 0.5≤b<1, and 1−a−b>0), and the switching material layer may have a thickness of 5 to 15 nm.

According to one embodiment, the switching material layer may be subjected to high-pressure hydrogen annealing after a thin-film forming process for forming the chalcogen compound, and the high-pressure hydrogen annealing may be performed in an H₂ atmosphere at a temperature of 150 to 350° C. and a pressure of 1 to 25 atm for 5 to 120 minutes.

According to one embodiment, when the cell transistor is turned on and a voltage greater than a threshold voltage of the control element is applied to the control element, the switching material layer may function as a low-resistance conductor and may be configured to allow current to flow in both directions between the bit line structure and the cell capacitor, and when the cell transistor is turned off and a voltage less than the threshold voltage of the control element is applied to the control element, the switching material layer may function as a high-resistance insulator and may be configured to prevent the charges stored in the cell capacitor from leaking via the cell transistor.

According to one embodiment, the control element and the cell capacitor may be connected in series while sharing the second electrode, wherein a lower surface and an upper surface of the second electrode may be in contact with an upper surface of the switching material layer and a lower surface of the capacitor dielectric layer, respectively, a lower surface of the switching material layer may be in contact with an upper surface of the first electrode, and an upper surface of the capacitor dielectric layer may be in contact with a lower surface of the third electrode, and the semiconductor memory device may further include a storage contact plug in contact with the second impurity region, wherein an upper surface of the storage contact plug may be in contact with a lower surface of the first electrode.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a schematic circuit diagram for describing a unit memory cell of a semiconductor memory device according to embodiments of the present invention;

FIG. 2 is a graph illustrating a voltage-current curve of a control element according to embodiments of the present invention;

FIG. 3 is a cross-sectional view for describing a hybrid capacitor according to one embodiment of the present invention;

FIGS. 4 and 5 are cross-sectional views for describing a hybrid capacitor according to other embodiments of the present invention;

FIG. 6 is a plan view for describing a semiconductor memory device including the hybrid capacitor according to one embodiment of the present invention; and

FIG. 7 is a cross-sectional view taken along line A-A′ in FIG. 6.

### DETAILED DESCRIPTION OF EXEMPLARY EMBODIMENTS

Advantages and features of the present invention and methods of achieving them will become clear through the following embodiments described in detail with reference to the accompanying drawings. However, the present invention is not limited to the embodiments described below, but may be implemented in various different forms. The present embodiments make the disclosure of the present invention complete and are provided to completely inform those of ordinary skill in the art of the scope of the disclosure, and the present invention is defined only by the scope of the claims. Throughout the specification, like reference numerals refer to like components.

In the present specification, when a member is said to be located “on” another member, this includes not only a case in which a member is in contact with another member, but also a case in which still another member is present between the two members. In addition, in the present specification, when a part is said to “include” a component, this means that it may include additional components, rather than excluding other components, unless specifically stated to the contrary.

As used throughout this specification, the terms “about,” “substantially,” or the like, which represent a degree, are used to mean at or close to numerical values when manufacturing and material tolerances inherent in the stated meanings are given, and they are used to help the understanding of the disclosure and prevent unscrupulous infringers from unfairly taking advantage of the contents in which accurate or absolute numerical values are stated

Hereinafter, embodiments of the present invention will be described in detail with reference to the accompanying drawings.

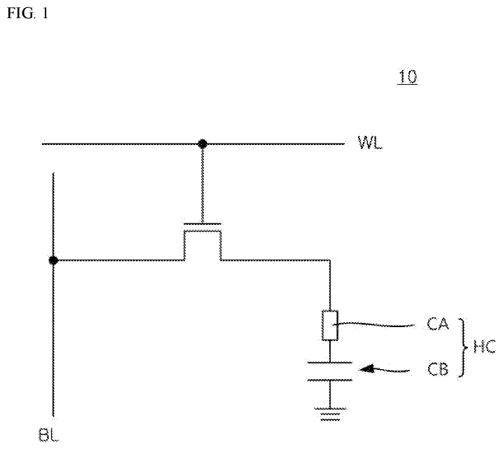

FIG. 1 is a schematic circuit diagram for describing a unit memory cell of a semiconductor memory device according to embodiments of the present invention.

Referring to FIG. 1, a semiconductor memory device 10 may include a cell transistor Tr and a hybrid capacitor HC, and the hybrid capacitor HC may include a control element CA and a cell capacitor CB connected in series.

The cell transistor Tr may be a field-effect transistor including a gate electrode, a source, and a drain. The gate of the cell transistor Tr is connected to a word line WL. In addition, the drain of the cell transistor Tr is connected to a bit line BL, and the source thereof is connected to one end of the control element CA. Here, the source and the drain are distinguished from each other by their functions, not simply by their name. Accordingly, in the present invention, the source and the drain may be referred to interchangeably.

The bit line BL may serve to supply power (e.g., a voltage or current), and the word line WL may serve to control the cell transistor Tr. For example, the cell transistor Tr may be turned on or off through a voltage applied to the word line WL, and when the cell transistor Tr is turned on, power, i.e., a voltage or current, may be applied to the hybrid capacitor HC. Alternatively, when the cell transistor Tr is turned off, the power applied to the hybrid capacitor HC may be cut off.

The cell capacitor CB may include a pair of electrodes and a capacitor dielectric layer interposed between the pair of electrodes. The cell capacitor CB may store charges in the pair of electrodes insulated from each other by the capacitor dielectric layer. That is, the semiconductor memory device 10 according to embodiments of the present invention may be a dynamic random-access memory (DRAM) device.

The control element CA may be a current control element capable of controlling the flow of current. The control element CA may be an element based on a threshold switching phenomenon having a nonlinear (e.g., S-shaped) I-V curve, and may include a pair of electrodes and a switching material layer interposed between the pair of electrodes. The switching material layer may include a material having ovonic threshold switching characteristics in which resistance may vary depending on the magnitude of a voltage applied to both ends of the control element CA. For example, the switching material layer may include a chalcogen compound containing a chalcogen element.

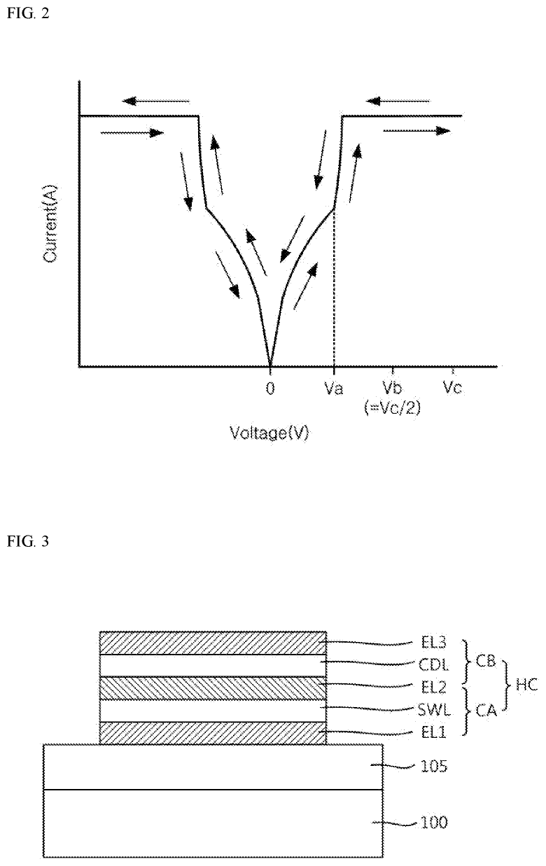

Hereinafter, an operation method of the semiconductor memory device according to embodiments of the present invention will be described with reference to FIG. 2.

FIG. 2 is a graph showing a voltage-current curve of the control element according to embodiments of the present invention.

Referring to FIG. 2, when a voltage less than a threshold voltage Va is applied to the control element CA, the control element CA is in a high-resistance state, and when a voltage greater than the threshold voltage Va is applied to the control element CA, the control element CA is in a low-resistance state and current may begin to flow. In addition, when the current flowing through the control element CA becomes less than a holding current (e.g., when the DRAM device is in a standby mode), the control element CA may be changed to the high-resistance state.

In addition, the threshold voltage Va of the control element CA may be implemented to have a value less than those of a read voltage Vb and a driving voltage Vc of the semiconductor memory device 10, i.e., the DRAM device (i.e., Va<Vb<Vc).

Accordingly, during operation (i.e., read or drive (write or erase) operation) of the DRAM device, the control element CA may function as a low-resistance conductor to allow current to flow in both directions between the bit line BL and the cell capacitor CB. In addition, in the standby mode of the DRAM device, the control element CA may function as a high-resistance insulator, and thus, current leakage via the cell transistor Tr can be blocked or reduced.

Specifically, when the DRAM device is in an operation state such as write, erase, or read, the cell transistor Tr may be turned on, and a voltage from the bit line BL may be applied to the cell capacitor CB in which the control element CA and the cell transistor Tr are connected in series. At this time, since the voltage (e.g., Vb or Vc) applied from the bit line BL is greater than the threshold voltage Va of the control element CA, the switching material layer of the control element CA functions as a low-resistance conductor, and accordingly, current (i.e., charges) can flow in both directions between the bit line BL and the cell capacitor CB so that the driving of the DRAM device can be performed normally.

Further, when the DRAM device is in a standby mode, the cell transistor Tr may be turned off, and a very low voltage, e.g., a voltage less than the threshold voltage Va, may be applied to the control element CA. In this case, the switching material layer of the control element CA may be changed to a high-resistance insulator. Accordingly, the cell capacitor CB is electrically isolated from the cell transistor Tr, and the switching material layer may form a potential barrier to prevent the charges stored in the cell capacitor CB from leaking via the cell transistor Tr. As a result, leakage current may be greatly reduced, thereby improving refresh characteristics and retention characteristics of the semiconductor memory device 10.

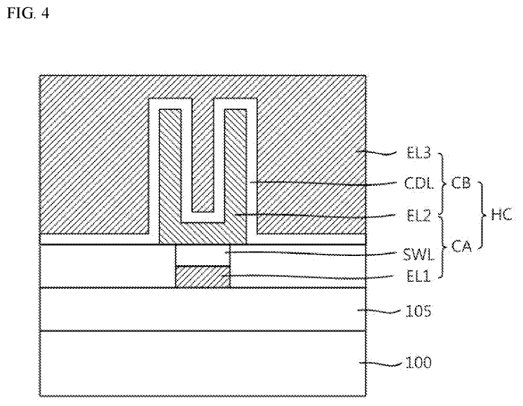

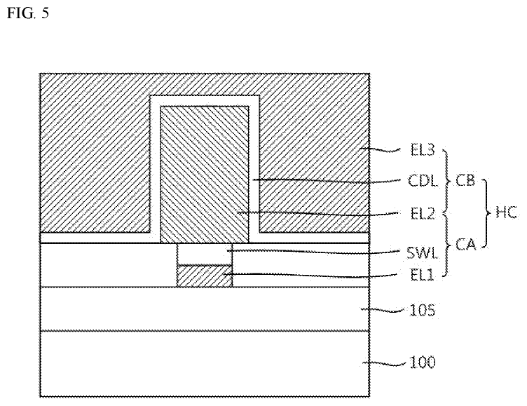

FIG. 3 is a cross-sectional view for describing a hybrid capacitor according to one embodiment of the present invention. FIGS. 4 and 5 are cross-sectional views for describing a hybrid capacitor according to other embodiments of the present invention.

Referring first to FIG. 3, a hybrid capacitor HC may include a first electrode EL1, a switching material layer SWL, a second electrode EL2, a capacitor dielectric layer CDL, and a third electrode EL3.

The hybrid capacitor HC may be provided on a lower structure 105 formed on a substrate 100. The lower structure 105 may include a cell transistor, a contact plug, and a bit line structure, and an interlayer insulating film covering the same.

Each of the first electrode EL1, the second electrode EL2, and the third electrode EL3 may include a doped semiconductor, a metal, a metal nitride, a noble metal, a conductive oxide, or a combination thereof. For example, each of the first electrode EL1, the second electrode EL2, and the third electrode EL3 may include at least one of impurity-doped silicon (Si), impurity-doped silicon germanium (SiGe), a metal material (e.g., Co, Ti, Ni, W, or Mo), a metal nitride (e.g., TiN, TiSiN, TiAlN, TaN, TaAlN, or WN), a noble metal material (e.g., Pt, Ru, or Ir), and a conductive oxide (e.g., PtO, RuO₂, IrO₂, SRO (SrRuO₃), BSRO ((Ba,Sr)RuO₃), CRO (CaRuO₃), or LSCo). Each of the first electrode EL1 and the third electrode EL3 may be formed through a physical vapor deposition (PVD) process, a sputtering process, or a chemical vapor deposition (CVD) process, but the present invention is not limited thereto.

The switching material layer SWL may be formed of a chalcogen compound containing a chalcogen element. Specifically, the switching material layer SWL may include a chalcogen compound obtained by combining at least one of Te and Se, which are chalcogen elements, and at least one selected from Ge, Sb, Bi, Al, Zn, B, Pb, Sn, Ag, As, S, Si, In, Ti, Ga, P, O, and C.

The first electrode EL1, the switching material layer SWL, and the second electrode EL2 may function as the control element CA described with reference to FIGS. 1 and 2. The threshold voltage Va of the control element CA may be controlled by adjusting the thickness or composition of the switching material layer SWL.

In one embodiment, when the driving voltage Vc of the semiconductor memory device (i.e., a DRAM device) of the present invention ranges from 1 V to 1.3 V and the read voltage Vb is Vc/2, the threshold voltage Va of the control element CA may be implemented to have a value less than the read voltage Vb, e.g., a value ranging from 0.3 V to 0.5 V.

For example, in order to implement such a threshold voltage Va, the switching material layer SWL may include A₁₋ₓTeₓ (where A includes C, B, Al, Zn, or Si, and 0.5≤x<1), Ge_{1-y}Se_{y} (where 0.5≤y<1), or GeₐSe_{b}Sb_{1-a-b} (where 0<a<0.5, 0.5≤b<1, and 1−a−b>0). In addition, the switching material layer SWL may have a thickness of 5 to 15 nm, preferably 7 to 12 nm.

The switching material layer SWL may be formed through a thin-film forming process such as an atomic layer deposition (ALD) process or a chemical vapor deposition (CVD) process.

According to one embodiment, the switching material layer SWL may be subjected to high-pressure hydrogen annealing after a thin-film forming process for forming the chalcogen compound. The high-pressure hydrogen annealing may be performed to improve the switching characteristics of the switching material layer SWL. For example, the high-pressure hydrogen annealing (HPHA) may be performed in an H₂ atmosphere at a temperature of 150 to 350° C. and a pressure of 1 to 25 atm for 5 to 120 minutes, preferably in an H₂ atmosphere at a temperature of 200 to 250° C. and a pressure of 5 to 15 atm for 5 to 120 minutes. The process conditions of the high-pressure hydrogen annealing may vary depending on the material and thickness of the thin film.

The capacitor dielectric layer CDL may include a high-k dielectric material. Here, the high-k dielectric material is defined as a material having a dielectric constant higher than that of silicon oxide. For example, the capacitor dielectric layer CDL may include hafnium oxide (HfO₂), zirconium oxide (ZrO₂), aluminum oxide (Al₂O₃), lanthanum oxide (La₂O₃), tantalum oxide (Ta₂O₃), titanium oxide (TiO₂), or a combination thereof. The capacitor dielectric layer CDL may be formed by physical vapor deposition (PVD), chemical vapor deposition (CVD), atomic layer deposition (ALD), or a combination thereof.

In one embodiment, the capacitor dielectric layer CDL may include a ferroelectric material. For example, the ferroelectric material may include hafnium oxide (e.g., HfO₂) or hafnium-zirconium oxide including at least one of nitrogen (N), tantalum (Ta), silicon (Si), germanium (Ge), lanthanum (La), yttrium (Y), scandium (Sc), strontium (Sr), aluminum (Al), and gadolinium (Gd).

The thickness of the capacitor dielectric layer CDL may have various sizes to achieve the required capacitance. For example, the capacitor dielectric layer CDL may have a thickness of 5 to 60 Å, but the present invention is not limited thereto.

The second electrode EL2, the capacitor dielectric layer CDL, and the third electrode EL3 may function as the cell capacitor CB described with reference to FIG. 1.

As described above, the first electrode EL1, the switching material layer SWL, the second electrode EL2, the capacitor dielectric layer CDL, and the third electrode EL3, which are sequentially stacked, may constitute the control element CA and the cell capacitor CB described with reference to FIGS. 1 and 2, and the control element CA and the cell capacitor CB may be connected in series while sharing the second electrode EL2 as an electrode layer. That is, a lower surface and an upper surface of the second electrode EL2 may be in contact with an upper surface of the switching material layer SWL and a lower surface of the capacitor dielectric layer CDL, respectively, a lower surface of the switching material layer SWL may be in contact with an upper surface of the first electrode EL1, and an upper surface of the capacitor dielectric layer CDL may be in contact with a lower surface of the third electrode EL3.

Since the operation method of the control element CA and the cell capacitor CB has been described with reference to FIGS. 1 and 2, a detailed description thereof will be omitted.

In the present embodiment, the second electrode EL2 is illustrated as having a flat two-dimensional shape, but the present invention is not limited thereto. The second electrode EL2 may have various three-dimensional structures for increasing a surface area to increase capacitance.

In an example, as shown in FIG. 4, the second electrode EL2 may have a cylindrical shape. In this case, the capacitor dielectric layer CDL may be provided along the surface of the second electrode EL2, and the third electrode EL3 may fill the inside of a cylinder and cover the second electrode EL2 on which the capacitor dielectric layer CDL is provided.

In another example, as shown in FIG. 5, the second electrode EL2 may have a pillar shape.

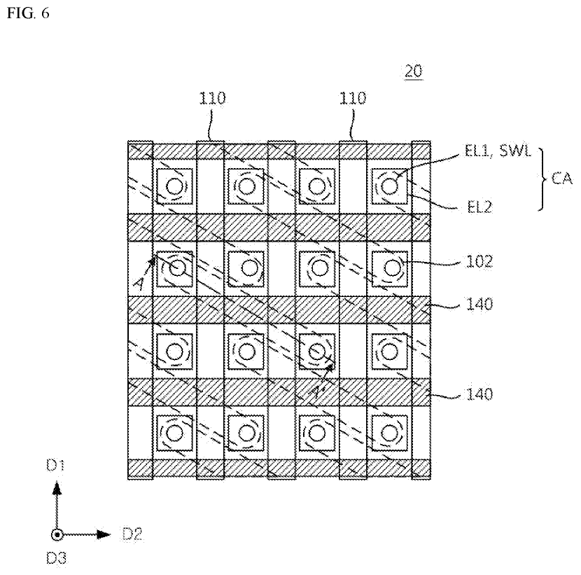

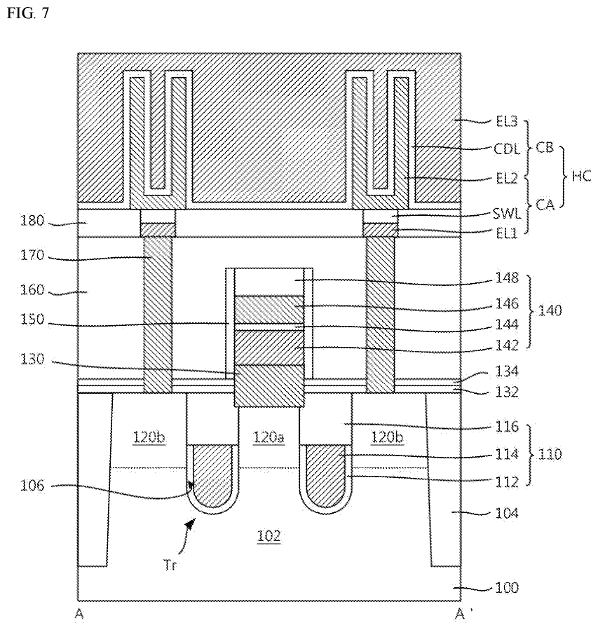

FIG. 6 is a plan view for describing a semiconductor memory device including the hybrid capacitor according to one embodiment of the present invention. FIG. 7 is a cross-sectional view taken along line A-A′ in FIG. 6.

Referring to FIGS. 6 and 7, a semiconductor memory device 20 includes a cell transistor Tr formed on a substrate 100, a hybrid capacitor HC, and a bit line structure 140. One cell transistor Tr and one hybrid capacitor HC may constitute one unit cell.

The substrate 100 may include an active region 102 and a field region. The field region may be a region in which a device isolation film 104 is formed in a device separation trench included in the substrate 100. The active region 102 may be a region other than the field region.

Gate structures 110 buried in the substrate 100 may be provided. For example, a gate trench 106 extending in a first direction D1 parallel to an upper surface of the substrate 100 may be provided, and the gate structure 110 may be provided in the gate trench 106. The gate structure 110 may be the word line WL described with reference to FIG. 1.

In one embodiment, the gate structure 110 may include a gate insulating film 112, a gate electrode 114, and a capping insulating pattern 116. The gate structure 110 may be provided in a plurality arranged in a second direction D2 parallel to the upper surface of the substrate 100 and perpendicular to the first direction D1.

The gate insulating film 112 may include silicon oxide and/or a high-k dielectric material having a dielectric constant higher than that of the silicon oxide. For example, the high-k dielectric material may be a material including at least one of hafnium oxide (HfO), hafnium silicate (HfSiO), hafnium oxide nitride (HfON), hafnium silicon oxynitride (HfSiON), lanthanum oxide (LaO), lanthanum aluminum oxide, (LaAlO), zirconium oxide (ZrO), zirconium silicate (ZrSiO), zirconium oxide nitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (Al₂O₃), and lead scandium tantalum oxide (PbScTaO).

The gate electrode 114 may include impurity-doped or undoped polysilicon, a metal (e.g., W, Ti, Ta, or the like), a metal nitride (e.g., TiN, TSN, TaN, or the like) and/or a metal silicide. The capping insulating pattern 116 may include silicon nitride.

In one embodiment, the gate structure 110 may be implemented as a high-K metal gate structure.

Impurity regions 120a and 120b provided as source/drain regions may be provided on the active region 102 between the gate structures 110.

For example, the substrate 100 may include a first impurity region 120a electrically connected to the bit line structure 140 and a second impurity region 120b electrically connected to the hybrid capacitor HC. The gate structure 110, and the first impurity region 120a and the second impurity region 120b on both sides of the gate structure 110 may correspond to the cell transistor Tr described with reference to FIG. 1.

A buffer insulating pattern 132 and an etch stop pattern 134 may be provided on the active region 102, the device isolation film 104, and the gate structure 110. For example, the buffer insulating pattern 132 may include an oxide, such as silicon oxide, and the etch stop pattern 134 may include a nitride, such as silicon nitride.

The bit line structure 140 may be provided on the substrate 100. The bit line structure 140 may extend in the second direction D2 and may be provided in a plurality arranged in the first direction D1. Each of the bit line structures 140 may include a first conductive pattern 142, a barrier pattern 144, a second conductive pattern 146, and a capping pattern 148, which are sequentially formed.

The first conductive pattern 142 may include polysilicon doped with impurities. The barrier pattern 144 may include a metal silicide layer and/or a metal nitride layer formed on the metal silicide layer. In an example, the metal silicide layer may include at least one of WSi, TaSi, and TiSi. The metal nitride layer may include at least one of WN, TaN, and TiN. The second conductive pattern 146 may include at least one of W, Ti, and Ta. The capping pattern 148 may include at least one of silicon oxide, silicon nitride, and silicon oxynitride. The bit line structure 140 may be the bit line BL described with reference to FIG. 1.

Bit line contact plugs 130 may be provided between the bit line structures 140 and the first impurity regions 120a. The bit line contact plugs 130 may each include at least one of a doped semiconductor material (e.g., doped silicon), a conductive metal nitride (e.g., titanium nitride or tantalum nitride), a metal (e.g., tungsten, titanium, or tantalum), and a metal-semiconductor compound (e.g., metal silicide). The bit line contact plugs 130 may be connected to the first impurity regions 120a. A lower surface of each of the bit line contact plugs 130 may be lower than an upper surface of each of the device isolation films 104.

A spacer 150 may be provided on sidewalls of each of the bit line structures 140. The spacer 150 may be formed of silicon nitride.

A first interlayer insulating film 160 covering the bit line structures 140 may be provided on the substrate 100. The first interlayer insulating film 160 may be formed of silicon oxide and/or silicon nitride.

Storage contact plugs 170, which pass through the first interlayer insulating film 160, the etch stop pattern 134, and the buffer insulating pattern 132 and come into contact with the second impurity regions 120b, may be provided. The storage contact plugs 170 may be disposed between the bit line structures 140 or on both sides of the bit line structure 140.

The hybrid capacitors HC may be provided on the storage contact plugs 170.

Each of the hybrid capacitors HC may include a first electrode EL1, a switching material layer SWL, a second electrode EL2, a capacitor dielectric layer CDL, and a third electrode EL3. The first electrode EL1, the switching material layer SWL, and the second electrode EL2 may function as the control element CA, and the second electrode EL2, the capacitor dielectric layer CDL, and the third electrode EL3 may function as the cell capacitor CB. For example, the control element CA is electrically connected to the second impurity region 120b and is configured to control the flow of current by changing its resistance according to the magnitude of an applied voltage. In addition, the cell capacitor CB may be connected in series to the control element CA and may function as a storage node configured to store charges.

Since the operation method of the control element CA and the cell capacitor CB, which are connected in series while sharing the second electrode EL2, and the material of each component have been described with reference to FIGS. 1 to 3, a detailed description thereof will be omitted.

Further, in the present embodiment, the second electrode EL2 is illustrated as having a cylindrical shape, but the present invention is not limited thereto. In another embodiment, the second electrode EL2 may have a flat two-dimensional plate shape as illustrated in FIG. 3, or a pillar shape as illustrated in FIG. 5.

Meanwhile, an upper surface of the storage contact plug 170 may be in contact with a lower surface of the first electrode EL1. In addition, the control element CA including the first electrode EL1, the switching material layer SWL, and the second electrode EL2 may be provided in a plurality by being arranged in the form of islands in the first direction D1 and the second direction D2 in a plan view. Each of the plurality of control elements CA may be connected to the corresponding storage contact plug 170.

A second interlayer insulating film 180 covering sidewalls of the first electrode EL1 and the switching material layer SWL may be provided on the first interlayer insulating film 160. The second interlayer insulating film 180 may include silicon oxide and/or silicon nitride.

According to embodiments of the present invention, when a semiconductor memory device (i.e., a DRAM device) is in a standby mode, a cell transistor is turned off and a voltage less than or equal to a threshold voltage thereof is applied to a control element of a hybrid capacitor, and thus, a switching material layer of the control element can be changed to a high-resistance insulator. Accordingly, the cell capacitor connected in series to the control element is isolated from the cell transistor, and the switching material layer can form a potential barrier to prevent charges of the cell capacitor from leaking via the cell transistor.

As a result, leakage current can be greatly reduced, so that a semiconductor memory device having improved refresh characteristics and retention characteristics can be provided.

While the embodiments of the present invention have been described with reference to the accompanying drawings, those skilled in the art will understand that the present invention can be implemented in other specific forms without departing from the technical spirit or the necessary features of the present invention. Therefore, it should be understood that the above-described embodiments and application examples are not restrictive but illustrative in all aspects.

What is claimed is:

1. A semiconductor memory device including a hybrid capacitor, the semiconductor memory device comprising:
a cell transistor including a gate structure provided on a substrate, and a first impurity region and a second impurity region disposed on the substrate at both sides of the gate structure;
a bit line structure electrically connected to the first impurity region; and
a hybrid capacitor including a control element electrically connected to the second impurity region and configured to control a flow of current by changing a resistance thereof according to a magnitude of an applied voltage, and a cell capacitor connected in series to the control element and functioning as a storage node configured to store charges,
wherein the control element includes:
a first electrode;
a switching material layer disposed on the first electrode and including a chalcogen compound containing a chalcogen element; and
a second electrode provided on the switching material layer, and
the cell capacitor includes:
the second electrode;
a capacitor dielectric layer provided on the second electrode and including a high-k dielectric material having a dielectric constant higher than that of silicon oxide; and
a third electrode provided on the capacitor dielectric layer.

2. The semiconductor memory device of claim 1, wherein the switching material layer includes a chalcogen compound obtained by combining at least one of Te and Se, which are chalcogen elements, and at least one selected from Ge, Sb, Bi, Al, Zn, B, Pb, Sn, Ag, As, S, Si, In, Ti, Ga, P, O, and C.

3. The semiconductor memory device of claim 2, wherein the switching material layer includes A₁₋ₓTeₓ (where A includes C, B, Al, Zn, or Si, and 0.5≤x<1), Ge_{1-y}Se_{y} (where 0.5≤y<1), or GeₐSe_{b}Sb_{1-a-b} (where 0<a<0.5, 0.5≤b<1, and 1−a−b>0), and
the switching material layer has a thickness of 5 to 15 nm.

4. The semiconductor memory device of claim 3, wherein the switching material layer is subjected to high-pressure hydrogen annealing after a thin-film forming process for forming the chalcogen compound, and
the high-pressure hydrogen annealing is performed in an H₂ atmosphere at a temperature of 150 to 350° C. and a pressure of 1 to 25 atm for 5 to 120 minutes.

5. The semiconductor memory device of claim 2, wherein when the cell transistor is turned on and a voltage greater than a threshold voltage of the control element is applied to the control element, the switching material layer functions as a low-resistance conductor and is configured to allow current to flow in both directions between the bit line structure and the cell capacitor, and
when the cell transistor is turned off and a voltage less than the threshold voltage of the control element is applied to the control element, the switching material layer functions as a high-resistance insulator and is configured to prevent the charges stored in the cell capacitor from leaking via the cell transistor.

6. The semiconductor memory device of claim 5, wherein the control element and the cell capacitor are connected in series while sharing the second electrode, wherein a lower surface and an upper surface of the second electrode are in contact with an upper surface of the switching material layer and a lower surface of the capacitor dielectric layer, respectively, a lower surface of the switching material layer is in contact with an upper surface of the first electrode, and an upper surface of the capacitor dielectric layer is in contact with a lower surface of the third electrode, and
the semiconductor memory device further comprises a storage contact plug in contact with the second impurity region, wherein an upper surface of the storage contact plug is in contact with a lower surface of the first electrode.
